(19) United States
(12) Patent Application Publication
(10) Pub. No.: US 2005/0048736 A1
(43) Pub. Date: Mar. 3, 2005

(54) Methods for adhesive transfer of a layer

(76) Inventors: Sebastien Kerdiles, Saint-Ismier (FR); Severine Bressot, Lariviere (FR); Fabrice Letertre, Grenoble (FR)

Correspondence Address: WINSTON & STRAWN;PATENT DEPARTMENT, 1400 L STREET, N.W., WASHINGTON, DC, 20005-3502, US

(21) Appl. No.: 10/746,202

(22) Filed: Dec. 23, 2003

(30) Foreign Application Priority Data
Sep. 2, 2003 (FR) 0310368

(51) Int. Cl. H01L 21/46

(52) U.S. Cl. 438/455

(57) ABSTRACT

In order to transfer a layer comprising for example at least one monocrystalline material, which preferably but not exclusively is a semiconductor material, from a first substrate to a second substrate, an adhesive may be deposited either on the transfer layer or the second substrate in a way so as to avoid forming a bond with the first substrate. The adhesive may, for example, be deposited over a maximum of the whole surface of the layer, and the second substrate may be bonded with the layer via the adhesive. Once bonded, the first substrate is may be released from the transfer layer, e.g., through detachment. The adhesive may be deposited on the layer to the maximum extent of the edges(s) of the film or layer when the edge(s) is/are set back from the edge(s) of the first substrate, or set back from the edge(s) of the film or layer when the edge(s) is/are plumb with the edge(s) of the first substrate.

### BACKGROUND

The present invention relates to methods for transferring layers between different supports and more particularly, to transferring layers between different supports with the use of an adhesive. In additional embodiments, the present invention relates to methods for transferring a layer for use in the field of optics, microelectronics, optoelectronics, or semiconductors in general.

In addition, the present invention relates to methods for transferring a film of a “source” substrate to an “acceptor” substrate, for example by metal bonding or by glue bonding. A film of a source substrate may for example be a film of Si, Ge, Sic, or GaN, or it can also be all or a portion of an opto-electronic or microelectronic device such as an LED (e.g., an LED based on AlGaInP or AlGaInN), a CMOS component, a solar cell (e.g., a solar cell based on Ge or III-V materials), etc.

Presently, there is an increasing number of applications (LEDs, CMOS components, solar cells, etc) that require “releasable” substrates, i.e., structures comprising a surface film or thin surface layer that can be separated from a support by means of a weak interface or buried zone. One example of an intended application that would benefit from a releasable substrate is an application in which a source substrate formed from sapphire is provided with a releasable thin film of GaN that can be used to grow the active layers of a blue LED, and can then be released to transfer the active layers to a Si or Cu support to provide better dissipation of the heat produced by the LED in operation.

In the field of non-releasable substrates, a bonding method is known which is carried out when fabricating high performance LEDs by epitaxially growing the active layers of the high performance LEDS on GaAs and transferring the active layers to a support that offers novel functionalities (transparency or a mirror effect). For example, the United Epitaxy Company (UEC) applies bonding using glue to transfer thin layers of AlGaInP onto sapphire from a GaAs substrate (S. J. Chang et al, IEEE Journal of Quantum Electronics, 38 (2002), 1390, “AlGaInP-sapphire glue bonded light-emitting diodes,” which is hereby incorporated herein by reference in its entirety). Another example is the use of metal bonding by the Visual Photonics Epitaxy Company (VPEC), to produce similar components (R. H. Horng et al, Applied Physics Letters 75, (1999), 154, “AlGaInP/AuBe/glass light emitting diodes fabricated by wafer bonding,” which is hereby incorporated herein by reference in its entirety). In these examples, the substrates are non-releaseable, the initial GaAs support generally being chemically etched for removal after bonding.

Regardless of whether the adhesive is glue or is metallic, the principles of said known bonding techniques are as follows:
(i) depositing the adhesive on one or both of the two surfaces to be bonded (i.e., a film or layer to be transferred to a first substrate and the second support), in particular depositing the adhesive over 100% of the surfaces, including the edges;
(ii) bringing the two surfaces into contact;
(iii) heat treating (T<500° C.) for several minutes, optionally under pressure to provide maximum adhesion.

These known techniques have deficiencies that may arise when they are applied to releasable substrates because such glue bonding or metal bonding reduce or destroy the releasability of the structure.

Thus, there are problems associated with developing a method that allows a film or layer to be transferred from a first substrate, which is sometimes termed the source substrate, wherein the source substrate is releasable, i.e., releasable, separable, or detachable from the film or layer that the source substrate maintains or supports, to a second substrate, which is sometimes termed the acceptor substrate. The present invention now overcomes these problems.

### SUMMARY OF THE INVENTION

In accordance with the principles of the present invention, methods are provided for transferring a layer comprising at least one monocrystalline material from a first substrate (e.g., a “donor” substrate) to a second substrate (e.g., an acceptor substrate), for example by adhesive bonding (e.g., metal bonding or glue bonding). The monocrystalline material is preferably but not exclusively a semiconductor material.

The arrangement initially constituted by the layer and the first substrate is confirmed to be releasable, e.g., the first substrate is intended to be detachable from the film.

Methods are provided according to the principles of the present invention for transferring a layer (“a transfer layer”) of at least one monocrystalline material (e.g., a monocrystalline semiconductor material) from a first substrate to a second substrate wherein the first substrate includes a support layer and weakened interface between the transfer layer and the support layer. An adhesive is deposited upon the transfer layer of the second substrate, or both, but not upon the interface so that the adhesive does not bond to the interface or the first substrate. The surface of the second substrate, which is positioned to face the transfer layer, is bonded to the transfer layer via the deposited adhesive. The transfer layer bonded to the second substrate can then be detached from the first substrate along the weakened interface to transfer the transfer layer to the second substrate.

The transfer layer may be a film or layer that is of sufficient dimension and structure to be transferred from a support through release, separation, detachment, etc. For convenience, the transfer layer is sometimes referred to herein as a film, layer, thin film, or thin layer.

The adhesive may be deposited up to a peripheral edge of the transfer layer. For example, the adhesive may be deposited on the transfer layer at a distance that is spaced from the peripheral edge of the transfer layer.

Another example involves depositing the adhesive on the entire transfer layer with the exception of its periphery. The structures may be arranged in various configurations. The first substrate may have a periphery that is greater than that of the transfer layer, or may have edges that are plumb with the transfer layer. Detaching the first substrate, in some instances, may leave a fraction of the transfer layer (e.g., on edge of the transfer layer) on the first substrate, which may then be removed (e.g., through etching). The detaching of the first substrate may also result in the complete removal of the transfer layer.

In the alternative, or in addition to depositing the adhesive on the transfer layer, the adhesive may also be deposited on a portion or all of the surface of the second substrate in the way as it was mentioned above in connection with depositing the adhesive on the transfer layer.

Methods are provided for transferring a layer of at least one monocrystalline material, preferably but not exclusively a semiconductor, from a first substrate to a second substrate. For example, an adhesive may be deposited over a maximum of the whole surface of the film or layer. The second substrate may be assembled or bonded and the film or layer via the adhesive and the film or layer may be detached from the first substrate. The maximum extent of the adhesive on the film or layer may for example be up to the edge(s) of the film or layer when said edge(s) is/are set back from the edge(s) of the first substrate; or be set back from the edge(s) of the film or layer when said edge(s) is/are plumb with the edges of the first substrate.

According to one aspect, a thin film, bonded to a source substrate by a weak interface, sustains a deposit of adhesive over the whole of its surface with the possible exception of its periphery, to prevent the formation of a deposit of an adhesive deposit or micro-welds at the edge of the wafer between the film and its support. A second substrate, optionally also coated with adhesive over a corresponding or lesser surface area, is bonded to the thin film coated with adhesive. The two substrates are then mechanically detached from each other, which results in a transfer of the film from the first to the second support.

If a film or thin layer is set back from the edges of the source substrate in all directions in a plane parallel to the plane of the film or layer, the adhesive can be deposited over the entire surface of said film or layer.

If a film or layer has the same lateral extension in all directions in a plane parallel to the plane of the film or layer, or has the same diameter as the source substrate, the adhesive can be deposited over the whole surface area of said film or layer with the exception of a peripheral zone or ring.

The final structure may comprise the acceptor substrate surmounted by a metal or adhesive deposit itself surmounted by a film comprising at least one monocrystalline material, which may be a semiconductor material.

### BRIEF DESCRIPTION OF THE DRAWINGS

Further features of the invention, its nature and various advantages will be more apparent from the following detailed description, taken in conjunction with the accompanying drawings in which like reference characters refer to like parts throughout, and in which:

FIGS. 1A to 2D are diagrams of illustrative sequences of processing involving two variations of an implementation of an embodiment of the present invention;

FIGS. 3A to 4B are diagrams of processing sequences illustrating adhesive bonding techniques that are known for use in the transfer of a layer transfer through chemical or mechanical thinning when those techniques are applied to a releasable substrate; and

FIGS. 5A, 5B, 6A and 7 are diagrams of illustrative sequences illustrating additional implementations of embodiments of the present invention.

### DETAILED DESCRIPTION OF THE PREFERRED EMBODIMENTS

A film or layer that is, for example, capable for forming the active components of optic, opto-electronic, or microelectronic devices, may be transferred from a support, which may be of suitable structural characteristic for the formation of the film or layer overlying the support, to another support having potentially different electrical, thermal, or structural characteristics through the use of an adhesive bond. The adhesive material may be deposited on one or both of the surfaces (the transfer layer and the receiving support) such as to avoid the formation of an adhesive bond with the support from which the transfer layer is to be released.

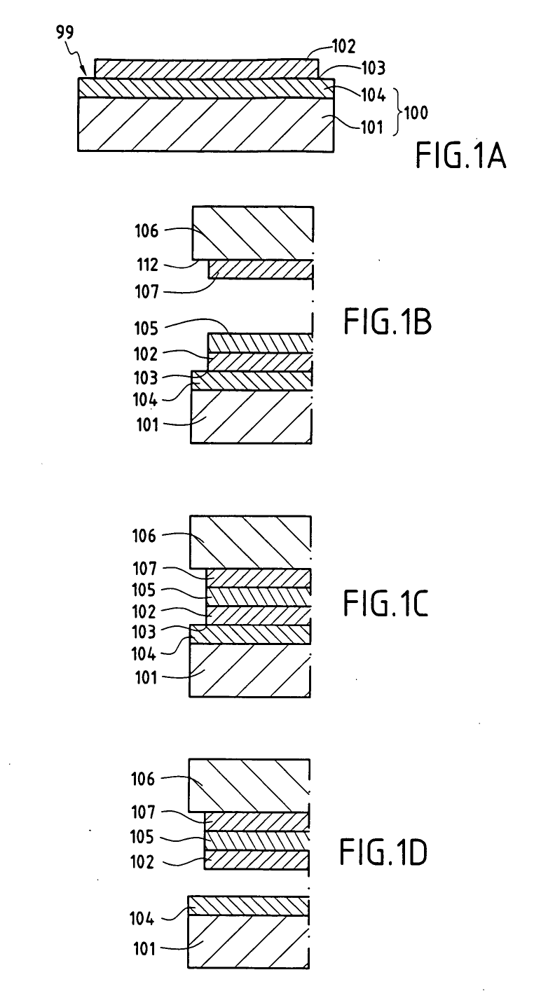

One example of adhesive bonding and transferring a film or layer from a releasable substrate (e.g., detachable substrate) is illustratively shown in FIGS. 1A to 1D. More specifically, FIGS. 1A-1D address methods in which a film or layer (e.g., a thin film) comprising at least one monocrystalline material is transferred from a first source substrate 100 to a second acceptor substrate 106, for example by metal bonding or by bonding using glue or resin.

The initial structure (FIG. 1A) is a releasable substrate which comprises film 102 comprising a monocrystalline material (e.g., only comprising a monocrystalline material) to be transferred that is supported by source substrate 100. The monocrystalline material is preferably a semiconductor material. However, monocrystalline material other than a semiconductor material such as sapphire may also be used and transferred from one support to another as shown herein. If desired, film 102 can also comprise other layers of different materials in addition to that of the monocrystalline material, as, for example, will be described below in connection with FIG. 7.

Film 102 can be released (e.g., detached) from support 100 by means of the presence of a weak interface or buried zone 103 located between film 102 and support 100. In some instances, weak interface or buried zone 103 may be formed partially or entirely from support 100, film 102, or the combination of the two. For convenience, weak interface or buried zone 103 is sometimes referred to herein as weak interface 103. Weak interface 103 results, for example, from implanting ionic or atomic species as described, for example, in PCT publication W002/084722 or in U.S. Pat. No. 5,374,564, or by porosification as described in U.S. Pat. No. 6,418,999, or by controlling the hydrophilic nature and roughness of the surfaces in contact at the weak zone, as described in U.S. Pat. No. 6,020,252: each of these documents are expressly incorporated herein in their entirety by reference thereto.

Weak interface 103 can also consist of a fine layer of a material with significantly less strength (e.g., structural strength) than that of the materials constituting film 102, substrate 101, or both.

In the example of FIG. 1A (and consequently in FIGS. 1B-1D), support 100 comprises substrate 101, which for example may be formed from a bulk semiconductor material, and further comprises insulating zone 104, which for example is an oxide.

The initial releasable substrate or support 100 preferably comprises ring 99, i.e., there is a difference in diameter or lateral extension between film 102 and support 100 on both sides of the plane defined by weak interface 103. If desired, film 102 and support 100 may be formed or positioned to have one or more edges that are plumb with each other (e.g., having an arrangement without ring 99). As such, ring 99 is referring to one example of a peripheral zone of support 100 that is an area on the periphery of 100 that is spaced apart and in some instances encircles the film or layer to be transferred (e.g., film 102).

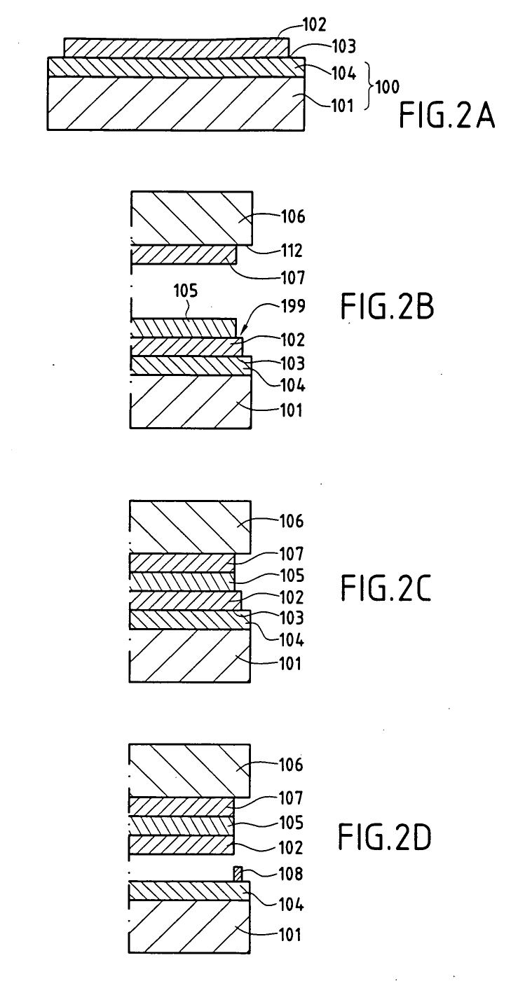

The surfaces to be bonded may be prepared for bonding using preparation techniques such as a cleaning step. After the application of any preparation techniques, adhesive 105 is applied to at least one of the two surfaces to be bonded, namely to the bonding surfaces of film 102 and/or acceptor substrate 106. Adhesive 105 may for example be glue, metal (e.g., a metal layer or metal stack), resin, or wax. Adhesive 105 can be deposited over the whole surface of film 102 (as shown in FIG. 1B), ring 99 of the releasable substrate remaining clear, or over only a portion of said surface (as shown in FIG. 2B).

Alternatively, or in addition, adhesive 107 can be distributed over acceptor substrate 106 such that only the surface intended to be brought into contact with film 102, or the surface intended to be brought into contact with film 102 where the surface is reduced by a new edge ring (FIG. 2C), receives the adhesive. The new edge ring may have a shape other than a ring (e.g., the shape of a square or one that does not have an encircled inner area).

The two surfaces to be bonded are then brought into contact and bonded by aligning the one or more zones coated with adhesive (FIG. 1C). In the case of metal bonding or simple bonding using glue, bonding can for example be carried out by dint of a heat treatment. Other techniques for bonding may also be used.

Once bonded, the initial support for film 102, is separated at weak interface 103, transferring film 102 onto acceptor substrate 106. The structure of film 102 and its initial support can, for example, be opened by inserting a thin blade at the weak interface. Chemical or heat treatment aimed at facilitating separation may be applied prior to the insertion of the thin blade. Other techniques may also be used.

The resulting structure would thus comprise acceptor substrate 106 surmounted by an adhesive deposit, which is itself surmounted by film 102 comprising a monocrystalline material (FIG. 1D). The separated (e.g., detached) donor substrate 100 can then be recycled (e.g., recycled in the same process to repeatedly transfer film to an acceptor substrate or for use in other substrate processing techniques).

In the method illustratively shown in FIGS. 1A-1D, film 102 is shown to completely transfer without edge losses. A variation of this technique is illustratively shown in FIGS. 2A-2D. In these figures, reference numerals that are identical to those in FIGS. 1A to 1D designate identical or corresponding elements. The variation resides in that adhesive 105 is deposited over the all of film 102 except at its edge, leaving second ring 199 clear of adhesive 105. The same surface area, reduced by edge ring 112 receives any adhesive on acceptor substrate 107. As mentioned above, this second ring may in some instances be used in shapes other than a circle.

The other steps (e.g. alignment, bonding) can be identical or similar to those described above with reference to FIG. 1C.

During separation, fraction 108 of film 102 may remain on the initial support (FIG. 2D). Fraction 108 corresponds to the zone of the film that did not receive an adhesive (i.e., the ring deliberately left clear of adhesive at the edge). This variation is less restricting with respect to alignment for bonding but results in the loss of a small fraction of the film (e.g., fraction 108).

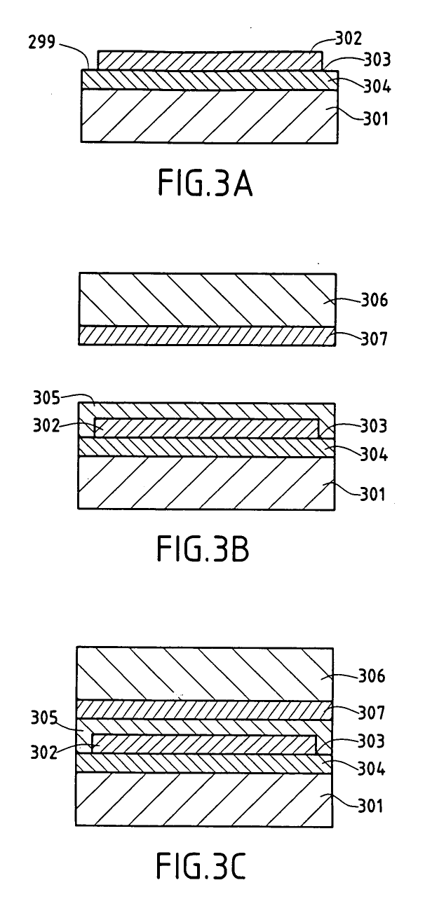

To illustrate some of the advantages of present invention, a processing sequence is illustratively shown in FIGS. 3A-3C in which the principles of known prior art techniques of transferring a layer from a “non-releasable” support to another support are applied to transfer a film or layer from a support that has a weakened interface with the film or layer. In FIGS. 3A-3C, a releasable SOI (silicon on-insulator) type substrate with ring 299 is shown.

The starting structure comprises, as also shown in FIG. 1A, film 302 that can be separated from source substrate 301 by dint of weak interface 303. One or more thin layers 304 can be intercalated between film 302 and support 301. For the purposes of bonding, a thin layer of adhesive 305 and/or 307 (glue, metal stack, resin, or wax) is deposited on one and/or the other of the two surfaces to be bonded (FIG. 3B), namely film 302 and its support 304 and/or acceptor support 306. The whole of one and/or the other of said two surfaces is coated with adhesive so that contact (FIG. 3C) between the two surfaces results in a strong bond that includes the edges of the wafers. In particular, the application of these known bonding techniques to releasable structures results in a bond that may cause adhesive 305-307 to irreversibly or non-releasably seal the periphery of the two supports 301 and 306, possibly via adhesive direct bonding of buried insulator 304 with acceptor substrate 306. As a result, the opening or detachment of the support cannot be carried out as the structure is no longer releasable because of the adhesive bond between the support and the acceptor substrate around the periphery of film 302. If an attempt is made to open such a sealed structure, i.e., to separate the supports, for example by inserting a blade between the two, the wafers break (e.g., because there is no weakened interface in areas in the periphery of film 303 where there is an adhesive bond, e.g., a micro-weld, with insulator layer 304).

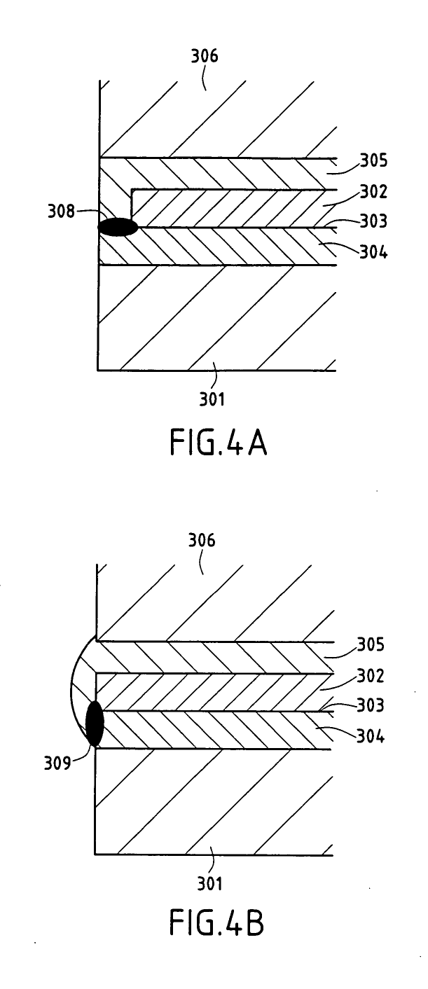

FIGS. 4A and 4B show details of the zones at the edge of wafers where micro-welds would appear, which would prevent the support from being released through mechanical separation at such points where a strong bond exists on either side of the plane defined by the weak interface. For example, in FIG. 4A, since film 302 has a slightly smaller diameter than source substrate 301 and intermediate layer(s) 304, adhesive 305 when bonded can produce micro-weld 308 between acceptor 306 and the edge of source support 301 (or 304). As shown in FIG. 4B, even if the diameter of film 302 is identical to that of the supports and other layers, micro-welds 309 could also occur over the edge of the wafer. This may for example be because, when bringing the surfaces to be bonded into contact, the adhesive may be crushed or spread (effect of pressure, surplus adhesive, etc) and thus run over the wafer depth and welding them fixedly to each other.

The techniques illustratively shown in FIGS. 1A-1D and 2A-2D can prevent the situations illustrated by FIGS. 4A and 4B, which may occur when a releasable source substrate is used to transfer a film or layer to an acceptor substrate using known principles of adhesive bonding mentioned above. As shown in FIGS. 1C and 2C, the adhesive preferably does not form a bond at any point of the structure between the two portions on either side of the plane defined by weak interface 103. Thus, releasability is not altered by any micro-welds at the edges. Furthermore, regardless of the variation employed, the methods illustratively shown herein for example in FIGS. 1A-1D and 2A-2D can completely or partially transfer the film, depending on the case, and are also compatible with subsequent release of the structure, because wafer edge micro-welds are avoided. Thus, the source and acceptor substrates can be separated without breaking the wafers. This means that initial support 101 can be recycled, in contrast to methods involving bonding followed by chemical etching used by UEC and VPEC, inter alias (see the prior art section above).

Further advantages reside in that long aggressive chemical etching steps aimed at removing the source substrate 100 are avoided and a solution for cases in which the latter substrate cannot be removed chemically is provided.

The variation, described with reference to FIGS. 2A to 2D, is also applicable in the case in which the initial substrate has no ring 199. Again, this avoids micro-welds such as those shown in FIG. 4B.

One particular example of an application of a method of the present invention will now be given. This example employs a SiCOI (SiC on insulator) substrate that is releasable and assembly by metal bonding. The releasable SiCOI substrate is obtained by the a “SMART-CUT” method which can produce a thin film connected to a substrate by molecular bonding. That technique, combining implantation and molecular bonding, is described in U.S. Pat. No. 5,374,564. If the bonding interface is strengthened, for example by heat treatment, the structure is, in some instances, no longer releasable. If, however, the bonding interface is not strengthened, but is kept reversible despite any annealing, then the structure formed, comprising a thin layer that is weakly connected to the support, is sometimes termed to be a releasable substrate. Examples of treatments that can limit the bonding energy are cleaning/chemical etching techniques that control roughness or the hydrophilic nature of the surfaces to be bonded (as for example described PCT publication W002/084722).

In this example, the method used is that illustratively described by FIGS. 2A to 2D. The releasable SiCOI substrate (FIG. 2A) is constituted by a support 101 formed from polycrystalline silicon (poly-SiC) surmounted by layer 104 of oxide onto which thin film 102 of monocrystalline silicon carbide (SiC) has been transferred. This substrate has ring 199 and a weak interface 103 between the oxide layer 104 and the SiC layer 102. The weak interface 103 results here from bonding by molecular bonding the bonding energy of which is controlled by the hydrophilic nature and the roughness of the surfaces that are brought into contact.

In this example, the acceptor substrate 106 is a silicon substrate (Si). After a cleaning step, the film sustains a deposit of metals (multi-layer) 105 over its entire surface, with the exception of the periphery. The outer ring may for example be protected by a screen during spray deposition (FIG. 2B). Acceptor substrate 106 is also metallized over a symmetrical surface (e.g. metallized to mate with the metals deposited over the film).

After aligning the surfaces to be bonded, the two wafers are brought into contact (FIG. 2C) and sealed under high vacuum. Heat treatment under mechanical pressure is applied to the structure using a piston, for example. The bonded structure is then chemically cleaned to facilitate mechanical opening, then a thin blade is inserted between the two wafers to separate them at the weak interface. The separation results in acceptor substrate 106 of Si that is coated with a metal layer and has a thin surface layer, layer 102, of SiC. The resulting source substrate comprises the oxide layer and residual ring 108 of SiC corresponding to the SiC that was deliberately not transferred (e.g., via the thin ring that has not received a metal deposit prior to bonding).

Another particular example of an application of the method of the present invention concerns releasable SOI type substrates, also produced using the SMART-CUT method, which is illustratively provided as follows. By applying the method of FIG. 1A, silicon support 101 may be provided that is optionally surmounted by layer 104 of SiO₂. Thin film 102 is weakly bound to the support via any buried insulator 104, by the presence of a weak interface 103 obtained by controlling the roughness of the bonded surfaces by molecular bonding.

In this example, film 102 comprises a thin layer of SiO₂ in its lower portion in contact with support 100 and a thin layer of monocrystalline silicon in its upper portion. In cases in which the structure is derived from SMART-CUT detachment, film 102 does not cover the whole surface of the support. The difference in diameter between film 102 and support 100 is typically about 1 millimeter (mm) to 5 mm and results in a step, the height of which is the thickness of the film (typically between approximately 10 nanometers (nm) and 5 micrometers (μm)), which can be considered to be the SOI ring. Additional aspects of the processing of FIGS. 1A-1D may be applied for the transfer and detachment of film 102.

In addition to SOIs produced using the SMART-CUT method, several other types of releasable substrates exist to which the techniques of the present invention can be applicable, including:
BSOI and BESOI type substrates fabricated by molecular bonding of two substrates, one of which is then thinned to constitute a thin film: examples of molecular bonding techniques are described in the work by Q. Y. Tong and U. Gösele, “Semiconductor wafer bonding” (Science and Technology, Wiley Interscience Publications) which is hereby incorporated by reference herein in its entirety;
substrates produced using the “ELTRAN” method in which the releasable interface is a fine layer of porous material; that method has been described, for example, in U.S. Pat. No. 6,020,252 or in the article by T. Yonehara et al, “Epitaxial layer transfer by bond and etch back of porous Si”, Applied Physics Letters 64 (16), p 2108-2110 (1994) which are hereby incorporated by reference herein in their entirety;
substrates weakened by the presence of cavities generated by implantation (cf U.S. published application No. 2003077885 which is hereby incorporated by reference in its entirety); and
substrates coated with a thin layer of low adherence.

All of said releasable or detachable or separable substrates have a ring with the exception of the last substrate.

The techniques of the present invention can also be applied to the following structures:
(i) releasable SiCOI substrates, similar to that given in the first example above, with support 101 constituted by mono- or polycrystalline SiC, sapphire or mono- or polycrystalline Si. The releasable film comprises monocrystalline SiC (preferably polytypes 6H, 4H or 3C);
(ii) substrates described in (i) onto which at least one AlN or GaN layer has been epitaxially grown prior to detaching. The thin layer to be transferred then comprises the monocrystalline SiC film and the epitaxially grown layer(s);
(iii) substrates described in (i) on which LED or laser diode structures based on GaN and other materials of the AlGaInN system (a source emitting in the blue, green and UV) have been produced. The thin layer to be transferred then comprises the film of monocrystalline SiC and the LED structures produced based on GaN and the other materials of the AlGaInN system;
(iv) releasable substrates with film 102 comprising GaAs weakly linked to a Si, GaAs, sapphire support;
(v) substrates described in (iv) on which LED or laser diode structures based on materials of the AlGaInP system (sources emitting in the red, orange and yellow) have been produced;
(vi) releasable SOI type substrates comprising a thin surface film of monocrystalline Si or SiGe, or partial or complete opto- or micro-electronic devices (CMOS, solar cells, photodetectors, etc).

The techniques of the present invention are described herein primarily for the case of circular substrates and films or layers. However, as mentioned above, such techniques are applicable to substrates and layers or films with other shapes, for example rectangular shapes. In the case of rectangular shapes, instead of any differences in diameter between the layer or film and the first substrate, there is a difference in the lateral extension of said various elements. In all cases, any contact between the bonding substance (adhesive, glue, metal stack) and the substrate initially carrying the layer or film is avoided to avoid any deleterious effects on the releasability of the system.

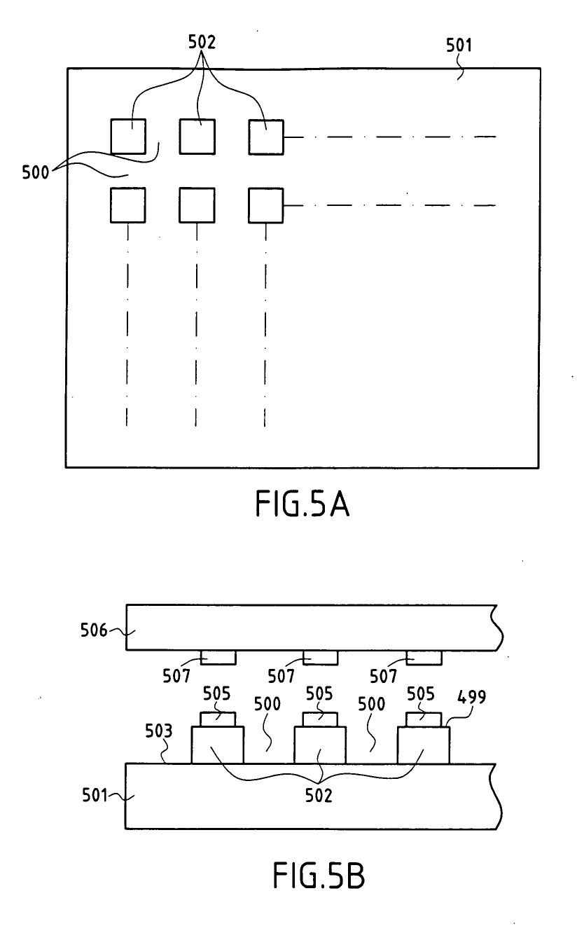

The techniques of the present invention can also be applicable to the case of films or layers 102 in which motifs have been produced, for example by photolithography. FIG. 5 shows the case of a square or rectangular substrate 501 onto which a film has been formed or deposited in a releasable manner as was the case for FIG. 1A. A supplemental etching step has produced islets 502 in said film separated by trenches 500.

A bonding substance 505 (for example an adhesive, glue or metal deposit) is then deposited on the studs or islets 502 over a maximum of the entire surface thereof and optionally leaving free ring or zone 499 on said surface. Said selective deposition of the bonding substance can be made using a screen or mask positioned over the system constituted by substrate 501 and studs 502 when depositing said substance. In similar manner, bonding substance 507 can be deposited in a selective manner over the second substrate 506. It would be possible to use the same screen or mask as that used previously to form studs 505.

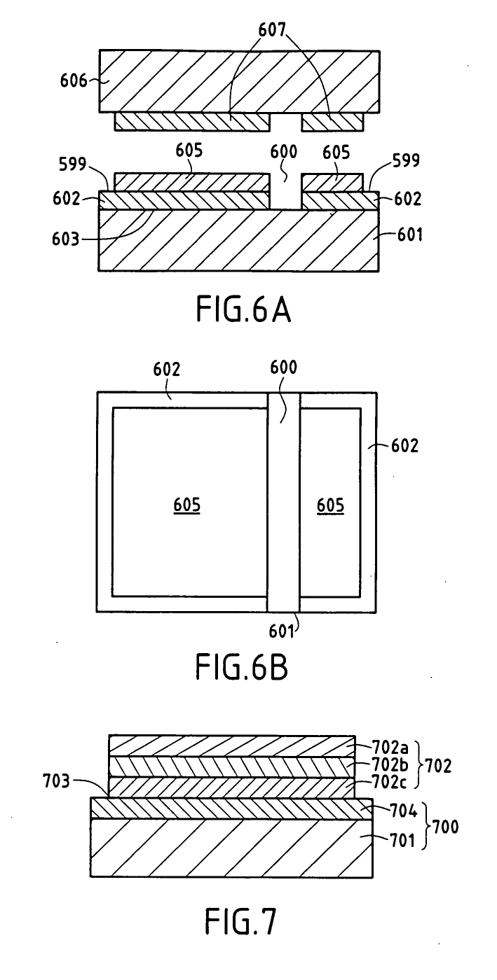

The steps for assembling the two substrates 501 and 506 and releasing studs 502 along weak interface 503 are identical to or similar to those already described in connection with FIGS. 1C and 1D or 2C and 2D. In accordance with a further implementation, shown in FIGS. 6A and 6B, initial substrate 601 supports film or layer 602 having groove or inner opening 600. Film 602 has the same lateral extension as the substrate 601 as shown. A bonding material 605 is deposited, leaving free outer margin 599, which may extend to the inner groove 600. It is then assembled with substrate 606 on which deposit 607 of bonding material may have been produced, and separated at weak interface 603.

In this example, as in the previous examples, it appears specifically that the adhesive is deposited:
set back from the edge of the film or layer when said edge is plumb with one edge of first substrate 601; or
at most up to the edge of the film or layer when said edge is set back from the edge of substrate 601 which is closest.

The thin film, which is transferred, may comprise one or more layers of different materials in addition to a layer of monocrystalline material. As shown in FIG. 7, film 702, supported by support 700 formed from substrate 701 and insulating zone 704, which is similar to those described above, comprises layer 702a of monocrystalline material, preferably a semiconductor material, and two layers 702b and 702c formed from materials different from that of layer 702a. As an example, layers 702b and 702c may be constituted by SiO₂, Si₃N₄ or A1₂0₃. Said film is transferred to an acceptor substrate in accordance with the techniques of the present invention in the same manner as with a mono-layer film as described above. The transfer method of the techniques of the present invention are thus also applicable to films constituted by a stack of a plurality of layers of different materials, with a layer of a monocrystalline material, preferably a semiconductor material, on the surface.

Depending on the type of weak interface involved, the processing that is applied in preparation for the release of substrate has to be controlled so as to avoid excessive damage (e.g., deterioration of detachability) to the weak interface (e.g., avoid heating the weak interface to the extent that it will cause bubbles previously created therein to burst).

Also, the present invention is not to be limited to the exact configurations described herein. Accordingly, all expedient modifications readily attainable by one of ordinary skill in the art from the disclosure set forth herein, or by routine experimentation therefrom, are deemed to be within the spirit and scope of the invention as defined by the appended claims.

1. A method of transferring a layer of at least one monocrystalline material from a first substrate to a second substrate wherein the first substrate includes a support layer and a weakened interface between the transfer layer and the support layer, which method comprises:
depositing an adhesive upon the transfer layer, but not upon the interface so that the adhesive does not bond to the interface or the first substrate,
bonding a surface of the second substrate to the transfer layer via the adhesive; and
detaching the transfer layer from the first substrate along the weakened interface.

2. The method of claim 1, wherein the transfer layer has a peripheral edge and the adhesive is deposited up to the edge.

3. The method of claim 2, wherein the adhesive is deposited on the transfer layer at a distance that is spaced from the peripheral edge of the transfer layer.

4. The method of claim 2, wherein the adhesive is deposited on the entire transfer layer with the exception of its periphery.

5. The method of claim 1, wherein the first substrate has a periphery that is greater than that of the transfer layer.

6. The method of claim 1, wherein the detaching leaves a fraction of the transfer layer on the first substrate.

7. The method of claim 6, wherein the fraction comprises an edge of the transfer layer.

8. The method of claim 1, wherein the detaching comprises complete removal of the transfer layer.

9. The method of claim 1, wherein the monocrystalline material is a semiconductor.

10. The method of claim 1, further comprising depositing the adhesive on a portion or all of the surface of the second substrate.

11. The method of claim 1, wherein the monocrystalline material is silicon, germanium, SiGe alloy, silicon carbide, gallium nitride, aluminum nitride, or sapphire.

12. The method of claim 1, wherein the transfer layer forms all or a portion of an opto- or micro-electronic device.

13. The method of claim 1, wherein the transfer layer forms all or a portion of a CMOS type component, a light-emitting component of an electroluminescent diode or laser diode type component, a light-detecting component, or a photovoltaic cell.

14. The method of claim 1, wherein the support layer comprises an insulator layer beneath the transfer layer that is to be transferred.

15. The method of claim 1, wherein the first substrate is the support layer and the weakened interface.

16. The method of claim 1, wherein the first substrate has, in all directions in a plane parallel to a plane of the layer, a lateral extension that is greater than that of the transfer layer.

17. The method of claim 16, wherein the difference between the lateral extension of the first substrate and that of the transfer layer is in the range of approximately 0.5 mm to 10 mm.

18. The method of claim 1, wherein the first substrate and the transfer layer form a silicon-on-insulator type structure.

19. The method of claim 1, which further comprises forming the weakened interface by providing a porous material between the transfer layer and the first substrate.

20. The method of claim 1, further comprising forming the weakened interface by providing cavities between the layer and the first substrate.

21. The method of claim 1, wherein the weakened interface is formed by forming the transfer layer as one that has weak adhesion to the first substrate.

22. The method of claim 1, wherein the first substrate is formed from a semiconductor or insulator material.

23. The method of claim 22, wherein the first substrate is formed from SiC, sapphire, silicon, GaAs or InP.

24. The method of claim 1, wherein the second substrate is formed from a semiconductor material, a metal, or a conductive ceramic.

25. The method of claim 23, wherein the second substrate is formed from silicon, SiC, aluminum, or copper.

26. The method of claim 1, wherein the adhesive is a glue, resin, or wax.

27. The method of claim 1, wherein the adhesive comprises a metal or alloy.
